(19) United States
(12) Patent Application Publication
(10) Pub. No.: US 2014/0021555 A1
(43) Pub. Date: Jan. 23, 2014

(54) MANUFACTURING METHOD OF SEMICONDUCTOR DEVICE AND SEMICONDUCTOR DEVICE

(71) Applicant: KABUSHIKI KAISHA TOSHIBA, Tokyo (JP)

(72) Inventors: Shota ISHIBASHI, Yokohama-Shi (JP); Shinya ARAI, Yokohama-Shi (JP); Gaku SUDO, Yokohama-Shi (JP)

(73) Assignee: KABUSHIKI KAISHA TOSHIBA, Tokyo (JP)

(21) Appl. No.: 13/780,140

(22) Filed: Feb. 28, 2013

(30) Foreign Application Priority Data
Jul. 23, 2012 (JP) 2012-162770

(51) Int. Cl. H01L 21/8234; H01L 27/088

(52) U.S. Cl. CPC H01L 21/823475; H01L 27/088
USPC 257/368; 438/294

(57) ABSTRACT

A manufacturing method of a semiconductor device according to an embodiment includes forming element isolation regions and active areas on a surface of a semiconductor substrate. A plurality of gate electrodes are formed above the active areas. Recesses that recess below surfaces of the element isolation regions are formed in the active areas by selectively etching the active areas between the gate electrodes. An interlayer dielectric film is deposited on the active areas, the element isolation regions, and the gate electrodes. A contact holes are formed on the recesses by etching the interlayer dielectric film using anisotropic etching. A bottom of each contact holes is widened by further etching the interlayer dielectric film on an inner wall of each contact hole using isotropic etching. Contacts contacting the recesses in the active areas are formed by embedding a conductive material in the contact holes.

### CROSS REFERENCE TO RELATED APPLICATIONS

This application is based upon and claims the benefit of priority from the prior Japanese Patent Application No. 2012-162770, filed on Jul. 23, 2012, the entire contents of which are incorporated herein by reference.

### FIELD

The embodiments of the present invention relate to a manufacturing method of a semiconductor device and a semiconductor device.

### BACKGROUND

Following downscaling and high integration of semiconductor devices, a contact resistance against a diffusion layer increases and the irregularity in the contact resistance increases. It is conceivable that a silicon substrate is etched on bottoms of contact holes after forming the contact holes so as to increase a contact area between each contact and each diffusion layer.

However, in this case, it is necessary to isotropically etch only silicon in the bottoms of the contact holes through the contact holes having a high aspect ratio. Because the silicon is etched through the contact holes, it is difficult to control the etching rate and the etching rate disadvantageously and possibly varies among the contact holes (or among wafers).

### BRIEF DESCRIPTION OF THE DRAWINGS

FIGS. 1 to 10B are plan views or cross-sectional views showing a method of manufacturing a semiconductor device according to the embodiment; and

FIGS. 11A and 11B are cross-sectional views showing the manufacturing method following FIGS. 10A and 10B and showing the semiconductor device according to the present embodiment.

### DETAILED DESCRIPTION

A manufacturing method of a semiconductor device according to an embodiment includes forming a plurality of element isolation regions and a plurality of active areas on a surface of a semiconductor substrate. A plurality of gate electrodes are formed above the active areas. A plurality of recesses that recess below surfaces of the element isolation regions are formed in the active areas by selectively etching the active areas between the gate electrodes. An interlayer dielectric film is deposited on the active areas, the element isolation regions, and the gate electrodes. A plurality of contact holes are formed on the recesses by etching the interlayer dielectric film using anisotropic etching. A bottom of each contact holes is widened by further etching the interlayer dielectric film on an inner wall of each contact hole using isotropic etching. A plurality of contacts contacting the recesses in the active areas is formed by embedding a conductive material in the contact holes.

Embodiments will now be explained with reference to the accompanying drawings. The present invention is not limited to the embodiments.

The present embodiment is applicable to cell transistors in various types of memory devices such as a magnetic random access memory (MRAM), a resistance random access memory (ReRAM), a phase-change random access memory (PRAM), and a ferroelectric random access memory (FeRAM). The present embodiment is also applicable to semiconductor devices other than the memory devices.

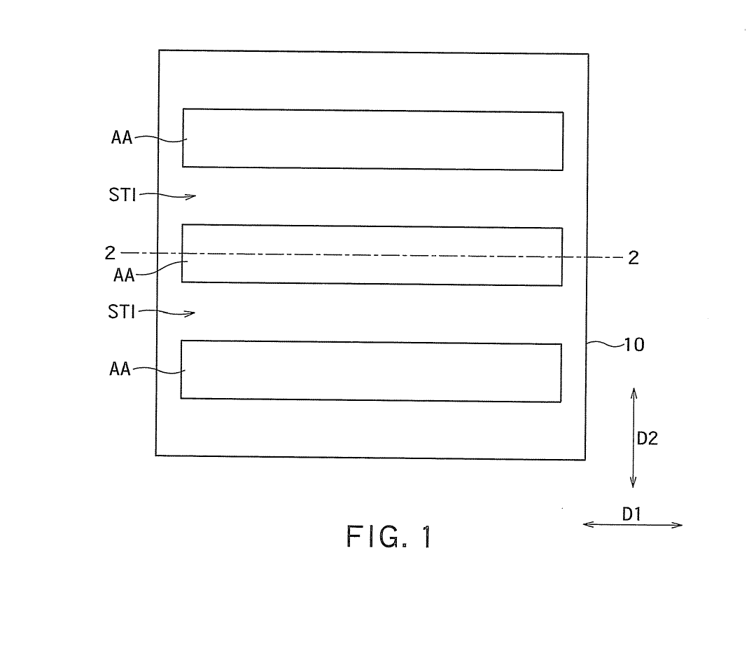

With reference to FIGS. 1 to 11B, a manufacturing method of a semiconductor device according to the present embodiment is explained. For example, the semiconductor device is a cell transistor in a memory device.

FIG. 1 is a plan view showing the manufacturing method of the semiconductor device according to the present embodiment. First, a semiconductor substrate 10 is prepared. The semiconductor substrate 10 is a silicon substrate, for example. Next, trenches are formed in the semiconductor substrate 10 by using lithography and RIE (Reactive Ion Etching), and filled with an insulation film. For example, this insulation film is formed by using a silicon oxide film by using HDP (High Density Plasma)-CVD. Element isolation regions STI (Shallow Trench Isolation) are thereby formed on a surface of the semiconductor substrate 10. As shown in FIG. 1, the element isolation regions STI define active areas AA. A plurality of active areas AA thereby extend in a first direction D1 and are formed into stripes. Each of the element isolation regions STI is provided between two adjacent active areas AA, and electrically isolates the two active areas AA from each other.

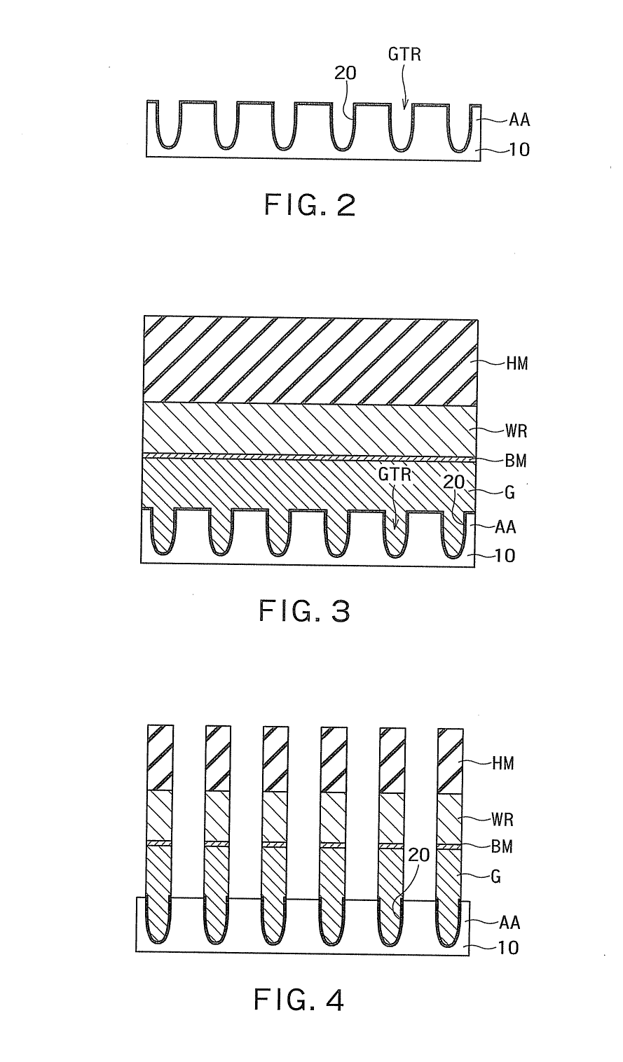

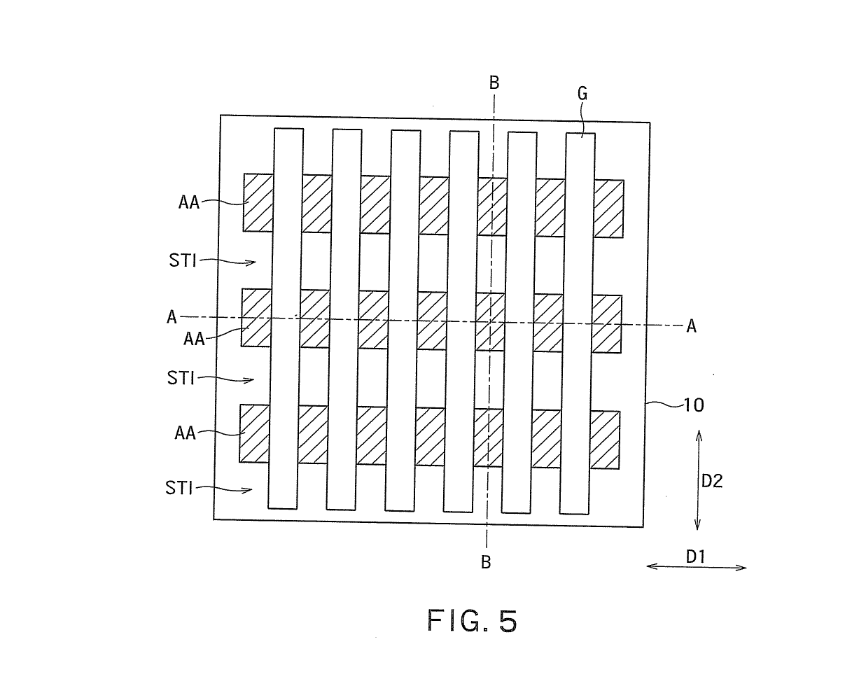

As shown in FIG. 2, gate trenches GTR are then formed in the active areas AA by using lithography and RIE. FIGS. 2 and 3 correspond to cross-sectional views taken along a line 2-2 of FIG. 1. The gate trenches GTR are formed in regions through which gate electrodes G pass in the active areas AA. That is, the gate trenches GTR extend in a direction D2 substantially orthogonal to the extending direction D1 of the active areas AA similarly to the gate electrodes G (see FIG. 5).

A gate dielectric film 20 is then formed on surfaces of the active areas AA and inner surfaces of the gate trenches GTR. The gate dielectric film 20 is formed by using, for example, a silicon oxide film or a high dielectric material (for example, a silicon oxynitride film or HfO₂) higher in a dielectric constant than the silicon oxide film.

Next, as shown in FIG. 3, a material of the gate electrodes G is deposited on the gate dielectric film 20. At this time, the material of the gate electrodes G is embedded in the gate trenches GTR. The material of the gate electrodes G is formed by using, for example, a conductive material such as polysilicon or metal.

After the material of the gate electrodes G is then planarized by using CMP (Chemical Mechanical Polishing), barrier metal layers BM are deposited on the gate electrodes G. The barrier metal layers BM are formed by using, for example, a conductive material such as TiN.

Wiring layers WR are then formed on the barrier metal layers BM and a material of hard masks HM is formed on the wiring layers WR. The wiring layers WR are formed by using metal such as tungsten or molybdenum, for example. The hard masks HM are formed by using an insulation film such as a silicon nitride film, for example. A structure shown in FIG. 3 is thereby obtained.

Next, the material of the hard masks HM is processed into layout patterns of the gate electrodes G by using lithography and RIE. Using the hard masks HM as a mask, the wiring layers WR, the barrier metal layers BM, and the materials of the gate electrodes G are processed into layout patterns of the gate electrodes G by using RIE. A structure shown in FIG. 4 is thereby obtained.

While the gate electrodes G are provided in the respective gate trenches GTR, the gate electrodes G can also be provided above the surface of the semiconductor substrate 10 differently from completely embedded gate electrodes.

A plan view at this stage is shown in FIG. 5. FIG. 5 is the plan view of the structure shown in FIG. 4. FIG. 5 shows an arrangement relation among the active areas AA, the element isolation regions STI, and the gate electrodes G. The gate electrodes G extend in the second direction D2 substantially orthogonal to the extending direction D1 of the active areas AA, and are arranged into stripes on a plane layout.

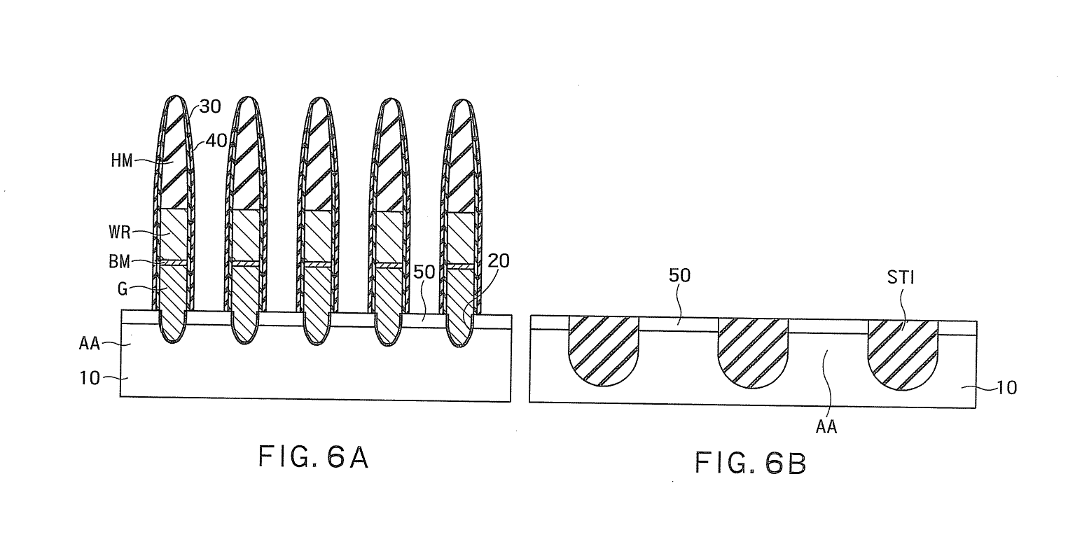

With reference to FIGS. 6A and 6B to 11A and 11B, the manufacturing method according to the present embodiment is further explained. FIGS. 6A, 7A, 8A, 9A, 10A, and 11A correspond to cross-sectional views taken along a line A-A of FIG. 5. FIGS. 6B, 7B, 8B, 9B, 10B, and 11B correspond to cross-sectional views taken along a line B-B of FIG. 5.

A spacer 30 and a sidewall film 40 are deposited on a side surface of each of the gate electrodes G, the barrier metal layers BM, the wiring layers WR, and the hard masks HM, and also deposited on the active areas AA and the element isolation regions STI. Each of the spacer 30 and the sidewall film 40 is formed by using an insulation film such as a silicon nitride film, for example. The spacer 30 and the sidewall film 40 are then etched back. The spacer 30 and the sidewall film 40 on the active areas AA and the element isolation regions STI are thereby removed while the spacer 30 and the sidewall film 40 are left on the side surface of each of the gate electrodes G, the barrier metal layers BM, the wiring layers WR, and the hard masks HM. A structure shown in FIGS. 6A and 6B is thereby obtained.

Next, using the spacers 30, the sidewall films 40, the hard masks HM, and the like as a mask, an impurity is ion implanted into the active areas AA. Diffusion layers 50 are thereby formed on the active areas AA. The diffusion layers 50 function as sources or drains, for example. An insulation film used as an etching stopper is not formed at this time.

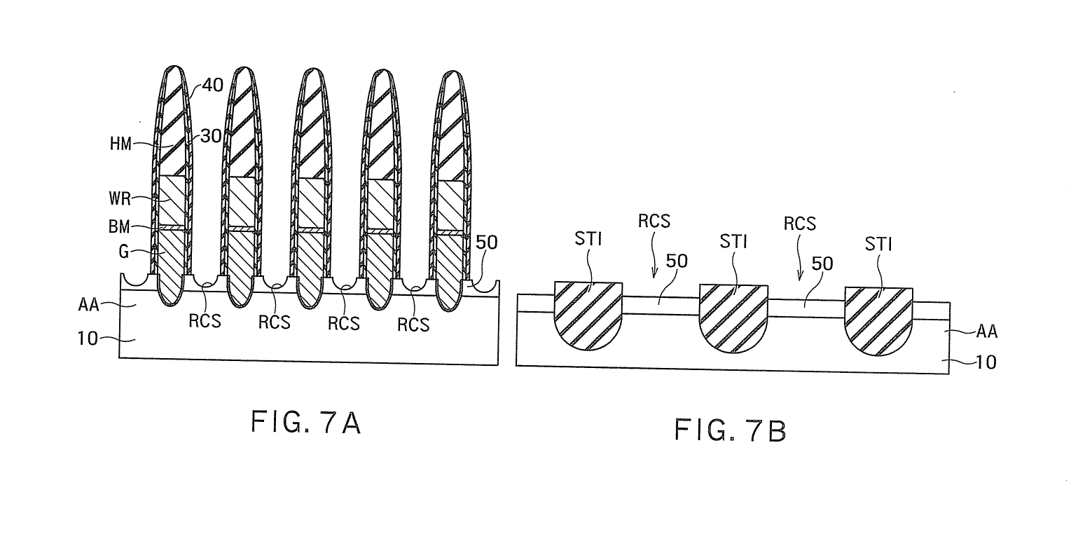

Next, as shown in FIGS. 7A and 7B, the active areas AA between the gate electrodes G are selectively etched, thereby recesses RCS are formed in the active areas AA. The active areas AA are etched in a self-aligned manner with the hard masks HM, the element isolation regions STI, the spacers 30, and the sidewall films 40 used as a mask. In the following explanations, the spacers 30 and the sidewall films 40 are also collectively referred to as a protective insulation film 30, 40.

Before etching, the active areas AA are almost equal in height to the element isolation regions STI. As shown in FIG. 5, on the plane layout, the active areas AA and the element isolation regions STI are arranged linearly and alternatively in the extending direction D2 of the gate electrodes G. Therefore, this indicates that it is very easy to form the recesses RCS in the present embodiment as compared with a case where the active areas AA are etched via small holes such as contact holes CH.

After the etching, the recesses recess down into positions below surfaces of the element isolation regions STI as shown in FIG. 7B. As shown in FIG. 7A, the recesses RCS are formed into circular arc shapes in a cross-section in the extending direction D1 of the active areas AA.

The recesses RCS are formed in the active areas AA other than regions covered with the gate electrodes G and the protective insulation film 30, 40. That is, in the plan view of FIG. 5, the recesses RCS are formed in shaded regions.

The hard masks HM and the protective insulation film 30, 40 function as not only the mask at a time of forming the diffusion layers 50 as described above but also as a mask at a time of forming the recesses RCS.

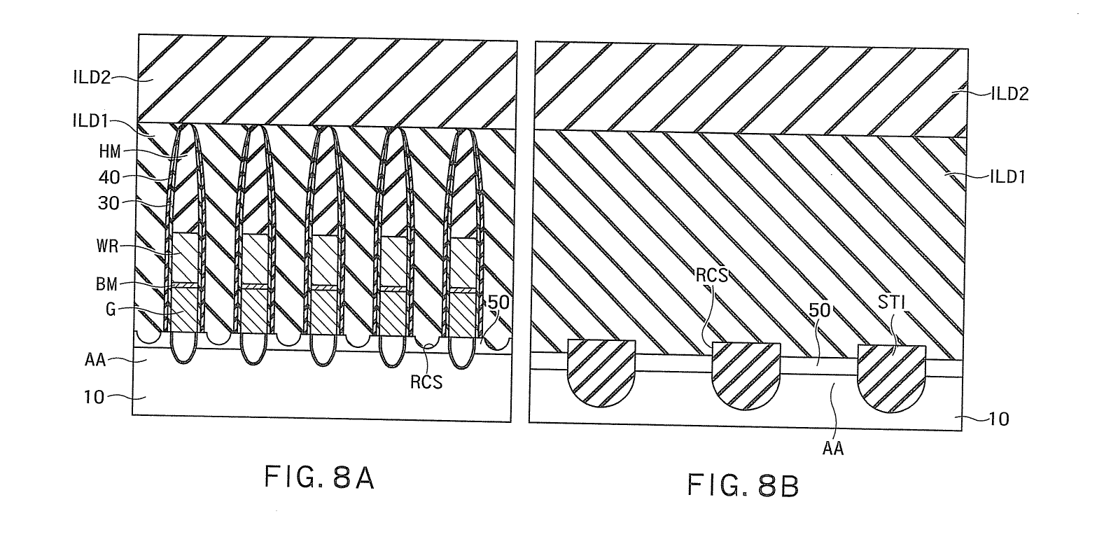

Next, as shown in FIGS. 8A and 8B, an interlayer dielectric film ILD1 is deposited on the active areas AA, the element isolation regions STI, and the gate electrodes G. After planarizing the interlayer dielectric film ILD1 by using CMP, an interlayer dielectric film ILD2 is deposited on the interlayer dielectric film ILD1. Each of the interlayer dielectric films ILD1 and ILD2 is formed by using, for example, an insulation film such as a silicon oxide film (polyimide).

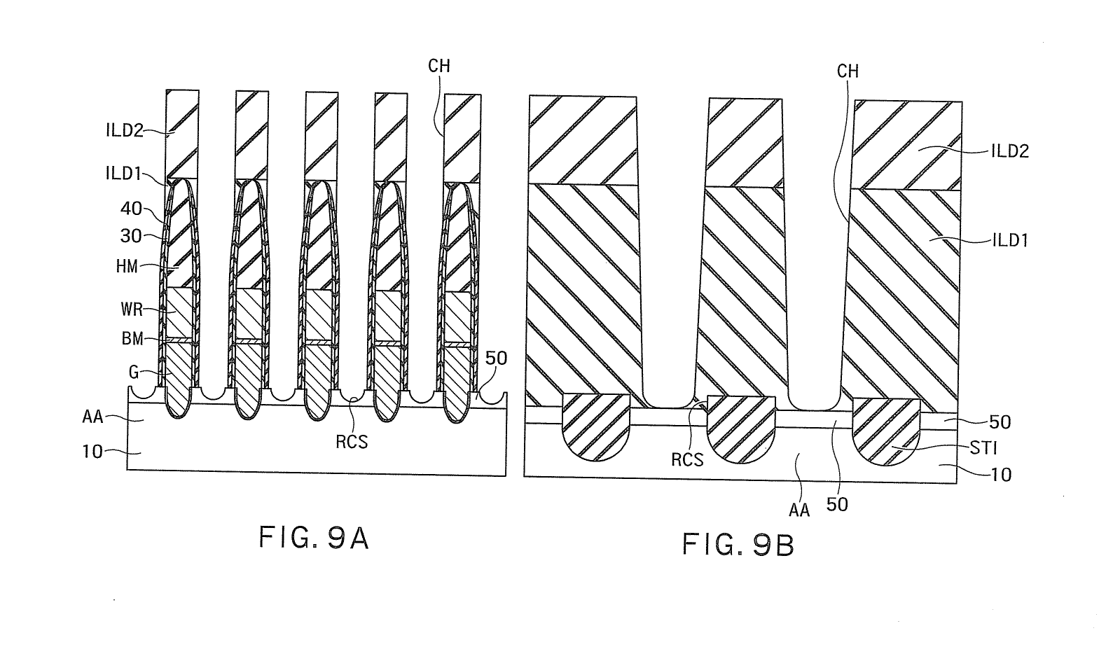

Next, as shown in FIGS. 9A and 9B, the contact holes CH are formed by using lithography and RIE. At this time, the interlayer dielectric films ILD1 and ILD2 are etched by using anisotropic etching, whereby the contact holes CH are formed on the recesses RCS between the adjacent gate electrodes G.

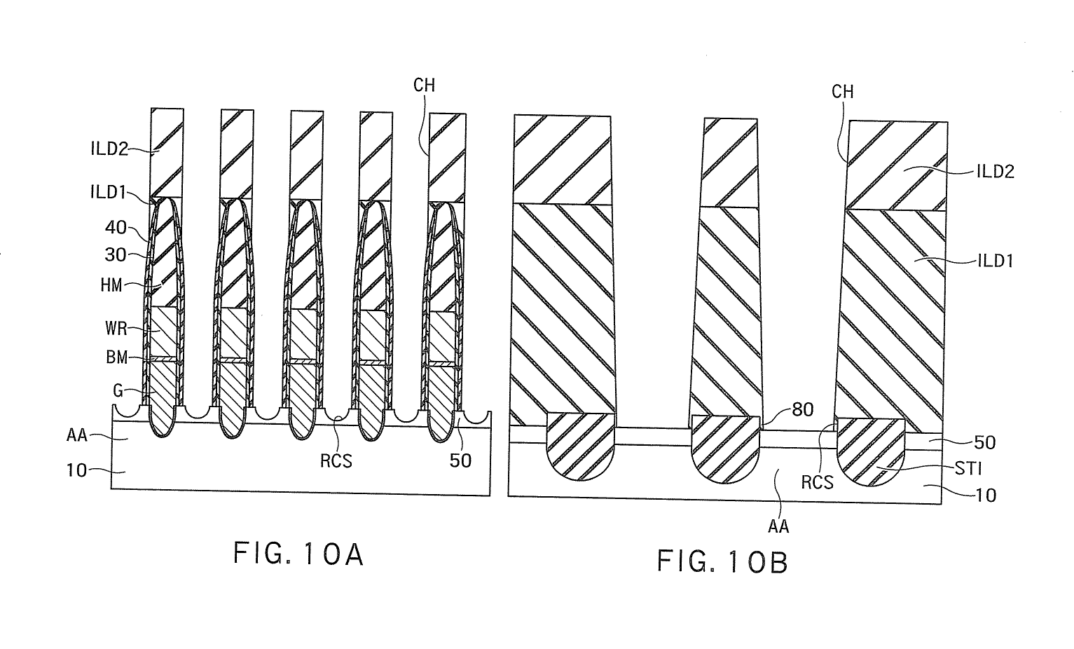

Thereafter, the interlayer dielectric films ILD1 and ILD2 on inner walls of the contact holes CH are further etched by using isotropic etching such as wet etching or CDE (Chemical Dry Etching). For example, wet etching using dilute hydrofluoric acid (DHF) is performed to etch the interlayer dielectric films ILD1 and ILD2 on the inner walls of the contact holes CH. This can widen bottoms of the contact holes CH and widely expose surfaces of the recesses RCS as shown in FIGS. 10A and 10B.

At this time, the bottoms of the contact holes CH can be widened to reach boundaries between the element isolation regions STI and the active areas AA. That is, the contact holes CH can contact side surfaces 80 of the element isolation regions STI in the boundaries between the element isolation regions STI and the active areas AA. However, no problem occurs even if the interlayer dielectric film ILD1 is left between the contact holes CH and the element isolation regions STI.

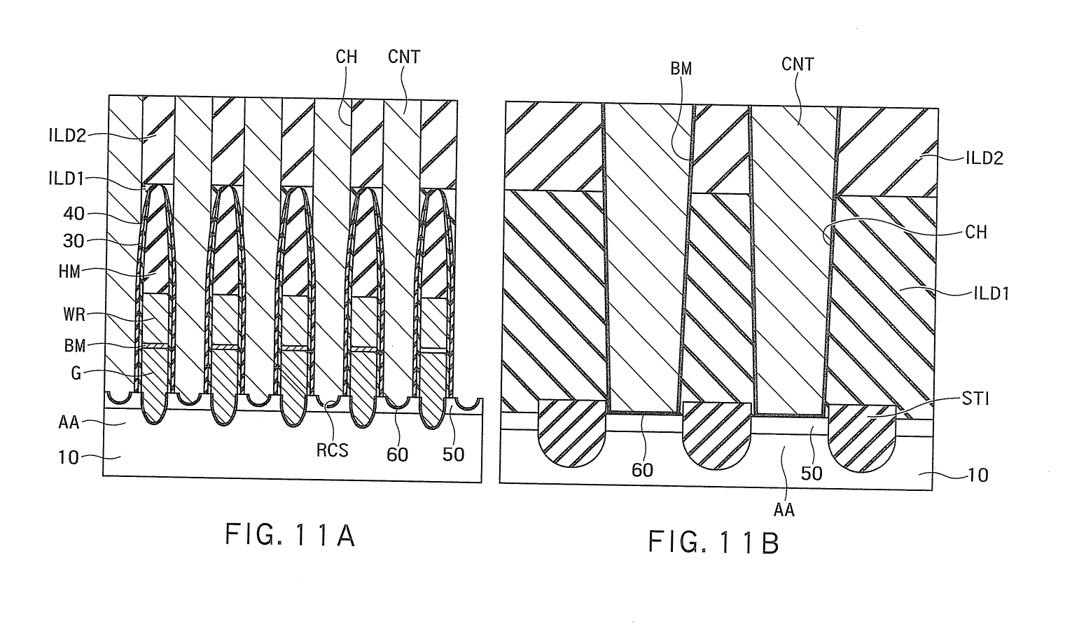

Next, as shown in FIGS. 11A and 11B, a silicide layer 60 is formed on the surfaces of the recesses RCS (the active areas AA). Barrier metals BM are formed on inner surfaces of the contact holes CH, respectively. The barrier metals BM are formed by using TIN, for example. Furthermore, a conductive material is embedded in each of the contact holes CH by using CVD (Chemical Vapor Deposition), thereby forming contacts CNT that contact the recesses RCS in the active areas AA. The contacts CNT are formed by using, for example, metal such as tungsten.

Thereafter, by forming a wiring layer, an interlayer dielectric film, and the like, the semiconductor device according to the present embodiment is completed.

In the present embodiment, the recesses RCS are formed after forming the diffusion layers 50. Alternatively, the recesses RCS can be formed before forming the diffusion layers 50 and then the diffusion layers 50 can be formed.

According to the present embodiment, the recesses RCS are formed in the active areas AA after the formation of the gate electrodes G and before the formation of the contact holes CH. At this time, the recesses RCS can be formed in a self-aligned manner in a memory region using the protective insulation film 30, 40 for the gate electrodes G and the element isolation regions STI as a mask without using the lithography.

Gaps between the adjacent gate electrodes G are linear and not holes like the contact holes CH. In addition, the distance between the adjacent gate electrodes G is larger than an opening diameter of each contact hole CH. Therefore, the manufacturing method according to the present embodiment can facilitate controlling an etching rate and make the irregularities in the size and the depth of the recesses RCS small, as compared with a case of etching the surfaces of the active areas AA via the contact holes CH. This can reduce the irregularity in a contact resistance.

Moreover, the recesses RCS are formed into circular arc shapes in the cross-section in the extending direction D1 of the active areas AA. In addition, the contact holes CH are formed to spread over between the adjacent element isolation regions STI. This makes a contact area between each contact CNT and each active area AA (the diffusion layer 50) wider than that according to a conventional technique. As a result, the contact resistance can be reduced.

When the element isolation regions STI are made by using the silicon oxide film formed by HDP-CVD, the silicon oxide film of the element isolation regions STI is higher in density than the polyimide of the interlayer dielectric films ILD1 and ILD2. Therefore, it is possible to etch the sidewalls of the contact holes CH to the side surfaces 80 of the element isolation regions STI while using the side surfaces 80 of the element isolation regions STI as an etching stopper. This can further reduce the contact resistance.

Furthermore, in the present embodiment, an etching stopper film is not provided on the active areas AA. Conventionally, it is necessary to perform over-etching to some extent so as to completely open all contact holes. Accordingly, at a time of forming the contact holes, an etching stopper film is provided on the active areas AA and the etching stopper film detects bottoms of the contact holes. After forming the contact holes, the etching stopper film on the bottoms of the contact holes are removed. Recesses are formed in the active areas AA via the contact holes.

On the other hand, in the present embodiment, there is no need to provide the etching stopper film for the following reasons. Although the over-etching is performed at a time of forming the contact holes CH, oxide films on the bottom of the contact holes CH formed during this over-etching are removed by a dilute hydrofluoric acid (DHF) treatment. In this case, diameters of the contact holes CH increase. However, the diameters of the contact holes CH have no problem, if memory elements such as MTJ elements are provided above the contact holes CH.

Furthermore, in the present embodiment, the recesses RCS are formed after the formation of the gate electrodes G. This enables the recesses RCS to be formed in a self-aligned manner. If the gate electrodes G are embedded gate electrodes that are embedded into position lower than the surfaces of the active areas AA, it is considered that a short-circuit does not occur between the gate electrodes G and the contacts CNT even when the recesses RCS are formed before the gate electrodes G. However, as described in the present embodiment, when the gate electrodes G are formed above the active areas AA and the recesses RCS are formed before the gate electrodes G, it is impossible to form the recesses RCS in a self-aligned manner with the gate electrodes G used as a mask. In this case, the contacts CNT possibly short-circuit with the gate electrodes G. On the other hand, when the recesses RCS are formed after forming the gate electrodes G as described in the present embodiment, it is possible to suppress the short-circuit between the contacts CNT and the gate electrodes G even if the gate electrodes G are provided above the active areas AA.

As a comparative example, when recesses were formed on bottoms of contacts via contact holes, the width of each recess was about 45 nm in a cross-section in the first direction D1. Furthermore, a contact area between each contact and each active area was about 910 nm².

On the other hand, when the same contacts CNT as those in the comparative example were formed by using the manufacturing method according to the present embodiment, the width of each recess RCS was about 92 nm. In addition, the contact area between each contact CNT and each active area AA was about 3,800 nm². That is, according to the present embodiment, the contact area between the contact CNT and the active area AA was about four times as large as that in the comparative example.

A configuration of the semiconductor device formed according to the manufacturing method in the present embodiment is explained next. The semiconductor device formed according to the present embodiment has the configuration as shown in FIG. 11. The semiconductor device includes the element isolation regions STI and the active areas AA provided on the surface of the semiconductor substrate 10. A plurality of gate electrodes G are provided above the active areas AA. The recesses RCS are provided on the surfaces of the active areas AA between the gate electrodes G, and recess below the surfaces of the element isolation regions STI. In the recesses RCS, the contacts CNT contact the active areas AA (the diffusion layers 50), and also contact the side surfaces 80 of the element isolation regions STI in the boundaries between the element isolation regions STI and the active areas AA.

The gate electrodes G extend to be substantially orthogonal to the active areas AA. Therefore, the recesses RCS and the contacts CNT are provided on the active areas AA between the gate electrodes G. The recesses RCS are formed into the circular arc shapes in cross-section in the extending direction D1 of the active areas AA.

Furthermore, in the present embodiment, not only the contacts CNT but also the gate electrodes G are formed into recess structures. That is, the gate electrodes G are formed so as to be embedded in the gate trenches GTR formed in the surfaces of the semiconductor substrate 10 and so as to protrude above the surface of the semiconductor substrate 10. Transistor channels are formed on the bottoms of the gate electrodes G and enable the adjacent diffusion layers 50 (sources and drains) to be conductive to each other.

According to the present embodiment, the contacts CNT contact the diffusion layers 50 in the recesses RCS, respectively. This can increase the contact area and thereby reduce the contact resistance. The bottoms of the contacts CNT reach the side surfaces 80 of the element isolation regions STI between the adjacent element isolation regions STI. This can further increase the contact area and thereby further reduce the contact resistance.

The silicide layer 60 can be provided between the active areas AA and the contacts CNT. This can further reduce the contact resistance.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of a semiconductor device, comprising:
forming a plurality of element isolation regions and a plurality of active areas on a surface of a semiconductor substrate;
forming a plurality of gate electrodes above the active areas;
forming a plurality of recesses that recess below surfaces of the element isolation regions in the active areas by selectively etching the active areas between the gate electrodes;
depositing an interlayer dielectric film on the active areas, the element isolation regions, and the gate electrodes;
forming a plurality of contact holes on the recesses by etching the interlayer dielectric film using anisotropic etching;
widening a bottom of each contact hole by further etching the interlayer dielectric film on an inner wall of the contact hole using isotropic etching; and
forming a plurality of contacts contacting the recesses in the active areas by embedding a conductive material in the contact holes.

2. The method of claim 1, comprising forming a protective insulation film covering the gate electrodes after forming the gate electrodes, wherein
when the recesses are formed, the active areas are etched in a self-aligned manner while using the element isolation regions and the protective insulation film as a mask.

3. The method of claim 1, wherein the recess is formed into a circular arc shape in a cross-section in an extending direction of the active areas.

4. The method of claim 2, wherein the recess is formed into a circular arc shape in a cross-section in an extending direction of the active areas.

5. The method of claim 1, wherein the bottom of each contact hole is widened to reach a boundary between one of the element isolation regions and one of the active areas by the isotropic etching.

6. The method of claim 2, wherein the bottom of each contact hole is widened to reach a boundary between one of the element isolation regions and one of the active areas by the isotropic etching.

7. The method of claim 3, wherein the bottom of each contact hole is widened to reach a boundary between one of the element isolation regions and one of the active areas by the isotropic etching.

8. The method of claim 1, wherein the isotropic etching is wet etching using dilute hydrofluoric acid.

9. The method of claim 2, wherein the isotropic etching is wet etching using dilute hydrofluoric acid.

10. The method of claim 3, wherein the isotropic etching is wet etching using dilute hydrofluoric acid.

11. The method of claim 1, comprising:
forming a silicide on the surfaces of the active areas after forming the contact holes; and
burying a conductive material in the contact holes after forming the silicide.

12. The method of claim 2, comprising:
forming a silicide on the surfaces of the active areas after forming the contact holes; and
burying a conductive material in the contact holes after forming the silicide.

13. The method of claim 3, comprising:
forming a silicide on the surfaces of the active areas after forming the contact hole; and
burying a conductive material in the contact holes after forming the silicide.

14. A semiconductor device comprising:
a semiconductor substrate;
a plurality of element isolation regions and a plurality of active areas provided on a surface of the semiconductor substrate;
a plurality of gate electrodes provided above the active areas;
a plurality of recesses provided in surfaces of the active areas between the gate electrodes, the recesses recessing below surfaces of the element isolation regions; and
a plurality of contacts contacting the active areas in the recesses, and contacting side surfaces of the element isolation regions in boundaries between the element isolation regions and the active areas.

15. The device of claim 14, wherein each recess is formed into a circular arc shape in a cross-section in an extending direction of the active areas.

16. The device of claim 14, further comprising a silicide provided between the active areas and the contacts.

17. The device of claim 15, further comprising a silicide provided between the active areas and the contacts.

18. The device of claim 14, wherein
a plurality of active areas extend in a first direction, and the gate electrodes extend in a second direction intersecting the first direction.

19. The device of claim 15, wherein
a plurality of active areas extend in a first direction, and
the gate electrodes extend in a second direction intersecting the first direction.
